(19) United States
(12) Patent Application Publication
(10) Pub. No.: US 2011/0210415 A1
(43) Pub. Date: Sep. 1, 2011

(54) FREESTANDING CARBON NANOTUBE NETWORKS BASED TEMPERATURE SENSOR

(76) Inventors: Claudia Altavilla, Fisciano (IT); Fabrizio Bobba, Fisciano (IT); Paolo Ciambelli, Fisciano (IT); Annamaria Cucolo, Fisciano (IT); Antonio Di Bartolomeo, Fisciano (IT); Filippo Giubileo, Fisciano (IT); Samanta Piano, Fisciano (IT); Diana Sannino, Fisciano (IT); Maria Sarno, Fisciano (IT); Alessandro Scarfato, Fisciano (IT)

(21) Appl. No.: 13/057,272

(22) PCT Filed: Aug. 6, 2009
(86) PCT No.: PCT/IB2009/053426

§ 371 Date: Mar. 4, 2011

(30) Foreign Application Priority Data
Aug. 8, 2008 (IT) SA2008A000022

(51) Int. Cl. H01L 29/66; C01B 31/02; C01B 31/00; H01L 21/768; B82Y 30/00

(52) U.S. Cl. 257/467; 423/448; 438/612; 977/742; 977/750; 977/752; 257/E29.166; 257/E21.575

(57) ABSTRACT

The present invention introduces a small-size temperature sensor, which exploits a random or oriented network of un-functionalized, single or multi-walled, carbon nanotubes to monitor a wide range of temperatures. Such network is manufactured in the form of freestanding thin film with an electric conductance proven to be a monotonic function of the temperature, above 4.2 K. Said carbon nanotube film is wire-connected to a high precision source-measurement unit, which measures its electric conductance by a standard two or four-probe technique. Said temperature sensor has a low power consumption, an excellent stability and durability, a high sensitivity and a fast response; its manufacturing method is simple and robust and yields low-cost devices. Said temperature sensor, freely scalable in dimension, is suitable for local accurate measurements of rapidly and widely changing temperatures, while introducing a negligible disturb to the measurement environment.

### FIELD OF THE INVENTION

The present invention relates to carbon nanotubes and in particular to the manufacturing of carbon nanotube networks (CNTNs), in the form of thin films, and their production as sensing elements in small size, low-power consumption, wide-range and fast temperature sensors. The network electric conductance is a stable parameter with a monotonic, non-metallic dependence on the temperature and is suitable to be exploited as the detecting physical quantity in negative temperature coefficient temperature sensors.

### BRIEF SUMMARY

The present invention introduces a small-size temperature sensor, which exploits a random or oriented network of un-functionalized, single or multi-walled, carbon nanotubes to monitor a wide range of temperatures. Such network is manufactured in the form of freestanding thin film with an electric conductance proven to be a monotonic function of the temperature, above 4.2 K. Said carbon nanotube film is wire-connected to a high precision source-measurement unit, which measures its electric conductance by a standard two or four-probe technique. Said temperature sensor has a low power consumption, an excellent stability and durability, a high sensitivity and a fast response; its manufacturing method is simple and robust and yields low-cost devices. Said temperature sensor, freely scalable in dimension, is suitable for local accurate measurements of rapidly and widely changing temperatures, while introducing a negligible disturb to the measurement environment.

### BACKGROUND OF THE INVENTION

Commercial solid-state temperature sensors have several limitations, the main ones being the limited range of operation, the reduced scalability, the non negligible power consumption and the high cost. In applications with widely changing temperature (as in cryogenic machines, in reaction chambers, on aircrafts or satellites, etc.), more sensors are needed, each for a specific temperature interval, and with obvious issues of costs, calibration and occupancy.

Several emerging fields of modern nanotechnology require accurate local measurements. Examples are the monitoring of temperature of chemical reactions, biological processes, several physical effects like the local joule heating in electronic microdevices or the heating from ionic/electronic focussed bombardment, etc. Temperature measurements in small size systems require miniaturized sensors with very limited perturbing effects and very high speed.

A carbon nanotubes (CNTs) based temperature sensor overcomes the listed shortages and fulfils several requirements, thanks to CNTs' dimensional characteristics and unmatched electric and thermal properties. It has a large working range, can be reduced in size up to micrometric dimension and can be operated with current as low as the μA with extremely low joule self-heating and perturbation for the system under measurement.

CNTs can be fabricated by a variety of methods which yield single (SW) or multiwalled (MW) tubular structures with diameters and lengths respectively in the nano and microrange. The catalytic chemical vapour deposition (CCVD) process, where the CNTs are obtained through pyrolitic decomposition of hydrocarbons on metallic catalysts (typically Fe, Ni or Co), to date, is the most convenient and exploited method to produce defect-free (multiwalled) carbon nanotubes.

So far, multiwalled carbon nanotubes (MWCNTs), which present a metallic electric behaviour and a Youg modulus of the order of the TPa, have mainly been used in composite materials as filler to enhance electric and mechanic properties as conductivity, stiffness, etc. For sensor and micro/nanoelectronic device applications, single-walled carbon nanotubes (SWCNTs), have been preferred in research laboratories for their simpler structure and a metallic or semiconducting electric behaviour controllable by their chirality and diameter.

Major obstacles presently preventing carbon nanotube commercial implementation in new classes of electronic devices and sensors are the care needed for their production, the lack of a technique for their assembly with precisely controlled positioning and orientation as well as the impossibility to control their chirality and diameter.

Only one patent, U.S. Pat. No. 7,217,374 B2 (Pub. Date May 24, 2007), proposes a resistive element constituted by a mesh of nanotubes between 2 metallic contacts and suggests that a temperature sensor exploiting the temperature dependence of the electric resistivity can be obtained from it. It is further proven that such element works in the temperature range of 300 to 700 K. In such patent, the mesh of CNT is obtained by cross-linking the CNTs to one another through cross-linked sites and consider several possible cross-linking chemical agents.

The present proposal instead deals with a freestanding film of nantotubes where the electric contacts among CNTs are spontaneously established without the need of any linking agent.

We prove that such film is suitable over a different and complementary temperature range, in particular also in the range 4-420 K, and we propose a simple method for its fabrication.

### OBJECTIVES OF THE INVENTION

An objective of invention is to employ freestanding networks of CNTs (CNTNs), easy to produce and manipulate, as temperature sensor. In particular, such networks are proven to constitute an electrically conducting layer, due to the spontaneously-established and high-quality electric contacts between intersecting CNTs. Their resistance has a monotonic non-metallic behaviour over a wide range of temperatures and gives the possibility of their usage for temperature sensing purposes in miniaturized thermistors.

Another objective of the invention is to realise small-sized devices fabricated with multiwalled carbon nanotube networks (MWCNTNs).

Objective of the invention is also to give methods to produce a temperature sensor (T sensor) using conventional fabrication technologies without affecting the CNT electrical properties.

Further objective is to produce sensors with wider temperature measurement range with respect to those presently on the market.

Finally, another objective is to realise a CNT-based sensor freely down-scalable and producible with reduced costs enabling the introduction of a miniaturized sensor for local measurement of temperature on small-size systems.

### SUMMARY OF THE INVENTION

The present invention realizes temperature sensors based on carbon nanotube networks (FIG. 1), oriented or not, with preference for the random ones, and provides methods for their manufacture.

The CNTs can be single walled or multiwalled, preferably MWCNTs. The CNTs can be synthesized by various technique, such as arc-discharge, laser ablation, gas-phase catalytic growth from carbon monoxide “Khassin et al.(1998)”, and chemical vapour deposition (CVD) of hydrocarbons preferably by chemical vapour deposition of hydrocarbons, more preferably carbon nanotubes are synthesized by catalytic chemical vapour deposition (CCVD) of ethylene on Co/Fe—Al₂O₃ catalyst. Specifically said method results in a very effective one, yielding high purity MWCNTs with more than 95% conversion of the injected carbon.

Said MWCNTs (FIG. 2) are used to prepare CNTNs (FIG. 4) in the form of freestanding thin films (FIG. 5), which can be manipulated, folded and cut. Said CNTN are sufficiently robust to let stable contacts, e.g. by metal evaporation, preferably with metal contact of Ag, Au, Cu, and more preferably with Ag, to be formed and to withstand sudden and long thermal stresses.

The resistance (or the conductance) of such CNTNs has been measured with a standard four-probe method (FIG. 1). In the realization of said sensor, the measurement is carried out by a commercial high precision source measurement unit (SMU) and converted to temperature. The temperature sensor is operated in continuous current mode and with a power consumption lower than 1 μW. Better accuracy in the temperature measurement, can be achieved by connecting the CNTN sensing element to an amplifying-filtering stage in a dedicated read-out electronics.

The resistance of said CNTN has a monotonic behaviour and decreases for rising temperatures on a wide range of temperatures, up to 600 K, specifically in the range 4-420K (FIG. 6). The R(T) curve is well fitted by a sum of two decreasing exponential functions and is easily converted to temperature (FIG. 6).

Said CNTN sensor has an excellent behavioral agreement and a faster response with respect to commercial thermistors (FIG. 7 and FIG. 8) as well as an excellent stability (FIG. 9).

An appropriately chosen packaging, which can be either a nanocomposite film or a polymeric matrix, with the function of protecting the device from environmental moistures and contaminants and of mechanically reinforcing it, completes the CNTN based temperature sensor.

Said temperature sensor is easily shrinkable and provides local accurate measurements of rapidly and widely changing temperatures, while reducing the possibility of disturbing the neighbouring environment.

### BRIEF DESCRIPTION OF THE DRAWINGS

FIG. 1: Measurement setup of the electrical conductance of carbon nanotubes films. A current is forced though the outer probes and the voltage arising between the innermost probes is measured in a standard four probe scheme. Shown in the picture are: the carbon nanotube network (1), the metal contacts (2), the current source (3) and the voltmeter (4).

FIG. 2: TEM image of as-produced MWCNTs

FIG. 3: Profiles of C₂H₄, C₂H₂, CH₄ and H₂ concentrations during CNT growth tests.

FIG. 4: Scheme of the different steps for the production of a random carbon nanotubes network.

FIG. 5: SEM images (a) of the carbon nanotube network and (b) a particular of it at higher magnification.

FIG. 6: Monotonic behaviour of the MWCNTN resistance as a function of the temperature.

FIG. 7: Comparison of the conductance values of a MWCNTN with the temperature measured by commercial thermistors.

FIG. 8: Temperature swings monitored through a MWCNTN and by commercial thermistors.

FIG. 9: Stability of the conductance of a MWCNTN used to monitor ambient, liquid helium and from liquid nitrogen rising temperature.

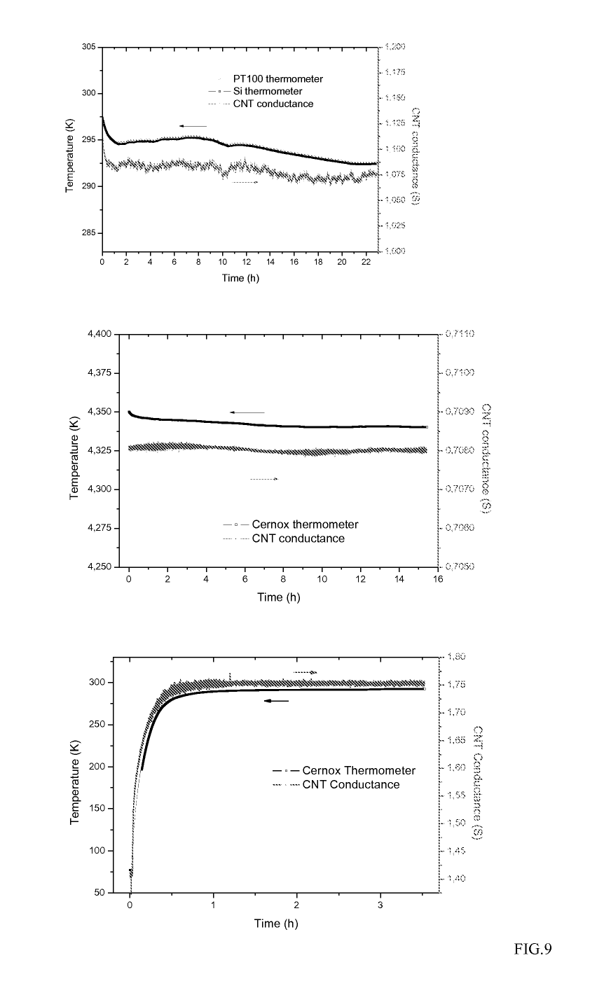

FIG. 10: Raman Spectra of as-prepared MWCNTs and of a final MWCNTN recorded with a 514 nm excitation wavelength.

### DETAILED DESCRIPTION OF THE INVENTION

Said MWCNTs are synthesized by hydrocarbon CCVD, more preferably ethylene CCVD on transition metal supported catalysts, more preferably Co/Fe—Al₂O₃ catalyst, following the steps listed below:

1. The catalyst is prepared by wet impregnation of gibbsite (γ-Al(OH)₃) powder with cobalt acetate (2.5 wt%) and iron acetate (2.5 wt %) ethanol solution.

2. The catalyst is then dried at 393 K for 720 min and preheated at 70 K/min up to 973 K under N₂ flow before CNT synthesis.

3. For the CNT synthesis a mixture of ethylene 10% v/v in helium is fed to a continuous flow microreactor at 973 K, with a runtime of 30 min. Gas flow rate and catalyst mass are 120 (stp)cm³/min and 400 mg.

4. To remove catalyst impurities, the grown MWCNTs are treated with 46% HF aqueous solution; a solid residue is afterwards extracted and washed with distilled water, then centrifuged and finally dried at 353 K for 12 h.

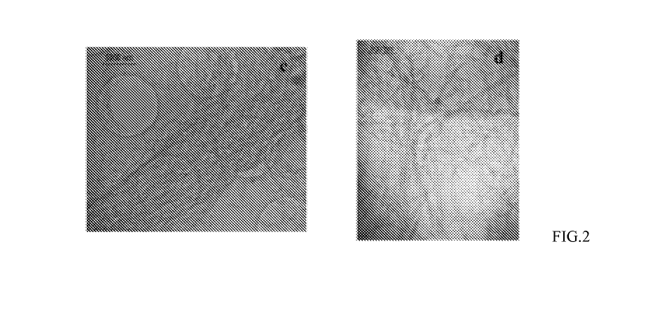

The final product are high purity MWCNTs, with a length in the range 100-200 μm and internal and external diameter of 10-30 nm and 5-10 nm respectively (a TEM image of them is shown in FIG. 2).

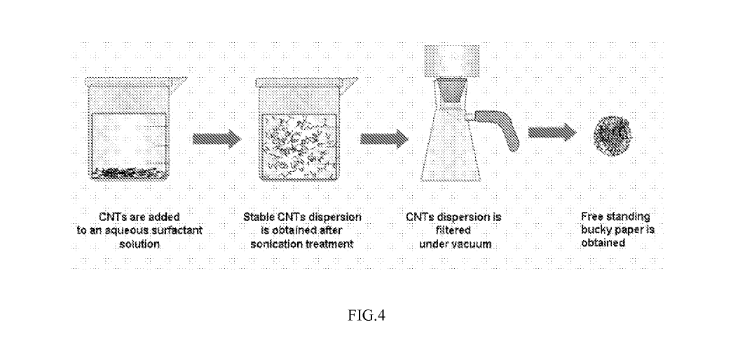

The MWCNTs are used to fabricate CNTNs in the form of thin films, with a fabrication procedure described below (FIG. 4):

5. 0.5 g of MWCNTs are suspended in 100 g of water in presence of 0.1 mg of sodium dodecyl sulfate and sonicated for 15 min

6. the solution is then vacuum filtered onto a membrane support.

7. after drying, films of different thickness and densities are removed from the support.

8. the thickness and density of CNTs in the films are easily controllable

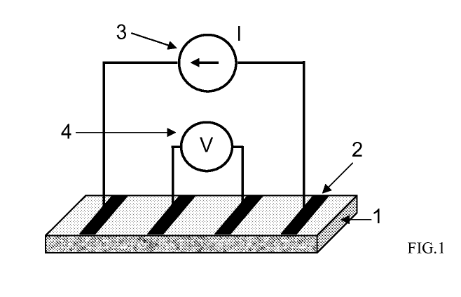

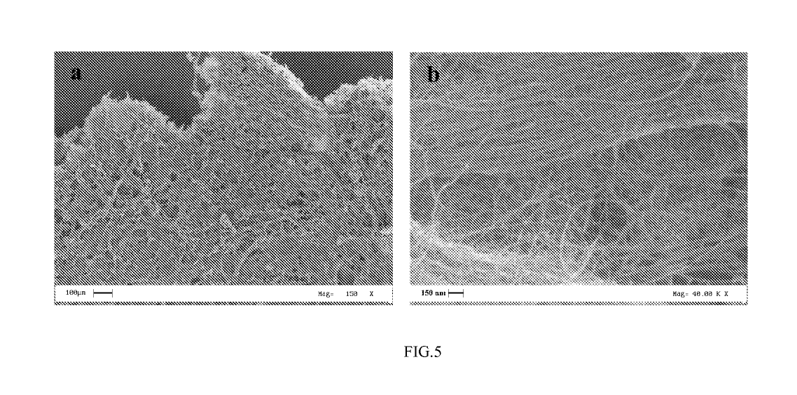

The so-obtained CNTNs (FIG. 5), typically with thickness of 100-300 um and diameter of 1-4 cm, can be folded and cut with scissor and are sufficiently robust to let stable contacts (by metal evaporation or, in a simplified embodiment, silver paint) to be formed and to withstand sudden and long thermal stresses. For the precise measurement of the resistance up to 6 metallic pads (contacts) are realised, with preference for 4 contacts. Due to the metallic nature of MWCNTs, the nanotube networks can be highly conductive and a multi-probe method is necessary to accurately measure their resistance (or conductance), by overcoming the problem of a comparatively non-negligible contact resistance (FIG. 1).

The contacts to the CNTN are realized by metal pads, of Ag or Au, evaporated on the CNT film in a high vacuum evaporator. The temperature of the metal source is around 800 K and the source-CNT film distance is 15-20 cm. The maximum local heating of the CNTN during the evaporation is estimated around 100 ° C. The pad geometry is defined by means of a metallic mask kept close to the CNT film. Metal strips of a few tens μm an thickness up to 20 μm are obtained and exploited as bonding pads for the metal wires connecting the MWCNTN sensor to the outside.

The high conductance is achieved by spontaneous cross-linking with good electric contacts of the MWCNTs and can be further increased and stabilized by a few thermal cycles (from room temperature up to 400° K), which evaporate adsorbates and residual impurities from the MWCNTs while tightening the spontaneously established interconnections.

To protect said CNTNs from environmental moistures and contaminants and to mechanically reinforce them, a nano-membrane is used as encapsulation.

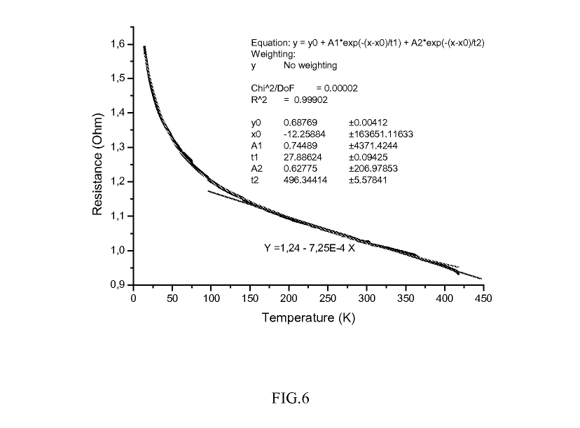

The resistance of MWCNTNs has a monotonic non-metallic behaviour over a wide range of temperatures (FIG. 6), which can be described by the sum of two exponential decays and is therefore easily converted to temperature.

The MWCNTN conductance fluctuations and consequently the sensitivity to temperature can be controlled and improved by increasing either the operating current or the accuracy in the current/voltage measurements. A high current could cause self heating, i.e. perturbation to the measurement environment, and a tradeoff has to be found for it; a better solution for higher accuracy is the introduction of a dedicated amplifying-filtering stage.

### EXAMPLES

### Materials and Chemicals

Cobalt acetate, gibbsite and iron acetate were obtained from Aldrich, bayerite (α-Al(OH)₃) from Sasol s.p.a..

Permanent gas and gaseous mixtures of high purity grade from SOL s.p.a Ag paste from Sigma-Aldrich Chimie Sarl.

### Example 1

### High Carbon Conversion Synthesis of MWCNT

The experimental plant for CNT syntheses consists of three sections: feed section, reaction section, analysis section. All the gas pipes (¼″ De) are of Teflon, connections and two, three and four way valves in stainless steel, to avoid any corrosion due to the presence of water in the reaction products.

The feed section allows the feeding with one or more hydrocarbons as source and uses N₂ as carrier gas. For each gas a mass flow controller is used, in order to assure a constant flow rate. The reaction section allows the preparation of carbon nanotubes in a reactor, consisting of a quartz tube of 300 mm length and 16 mm internal diameter. A quartz reactor, placed in a vertical furnace, is filled with a thin layer of catalyst particles that is crossed perpendicularly by the gaseous feed. An external quartz tube, internal diameter 35 mm, permitted the preheating of the reactants stream. In order to measure the temperature inside the reactor, a thermocouple is placed on a 4 mm internal diameter quartz shield, coaxial to the reactor. The furnace temperature and the control parameters are adjusted by a programmable temperature controller, connected to a type K thermocouple, located inside the reactor. A temperature reader connected to a second thermocouple measures the temperature of the catalytic layer inside the reactor.

The syntheses were performed in the experimental plant described below, equipped also with on-line ABB analysers that enables the monitoring of C₂H₄, C₂H₂, CH₄ and H₂ concentrations in the effluent stream on line during the reaction. Co, Fe catalysts (2.5 wt % of each metal) are prepared by dry impregnation with cobalt acetate and iron acetate solution of gibbsite (γ-Al(OH)₃). The catalyst is dried at 393 K for 720 min, and preheated before synthesis at 70 K/min up to 973 K under N₂ flow. For the CNT synthesis a mixture of ethylene 10% v/v in helium is fed to a continuous flow microreactor at 973 K, with a runtime of 30 min. Gas flow rate and catalyst mass are 120 (stp)cm³/min and 400 mg.

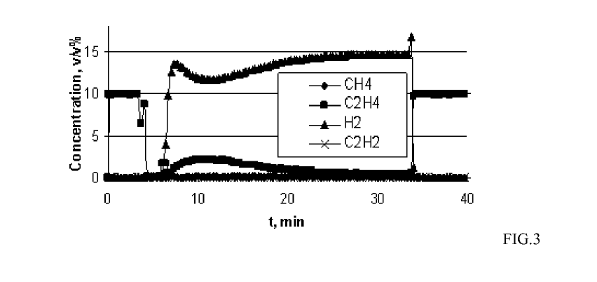

The profiles of C₂H₄, C₂H₂, CH₄ and H₂ concentrations during CNT growth tests are shown in FIG. 3. Ethylene concentration during the growth time reaches values lower than the 5% of the initial one. Hydrogen concentration reaches a plateau.

The ethylene conversion and hydrogen yield have been calculated by considering the ethylene conversion to carbon and hydrogen as the main reaction: C₂H₄→2C+2H₂

In relation to this reaction and initial feed composition, the expansion volume factor ε_{C2H4} can be calculated. Ethylene conversion and hydrogen yield can be expressed as:

$${X}_{C 2 H 4} = \frac{1 - \frac{{C}_{C 2 H 4}}{{C}_{C 2 H 4}^{0}}}{1 + \frac{{ɛ}_{C 2 H 4} * {C}_{C 2 H 4}}{{C}_{C 2 H 4}^{0}}} ; {R}_{H 2} = \frac{( 1 + {ɛ}_{C 2 H 4} {x}_{C 2 H 4} ) * {C}_{H 2}}{2 {C}_{C 2 H 4}^{0}}$$

where C means concentration and apex 0 is referred to initial one.

The ethylene conversion results higher than 95%.

### Example 2

### MWCNT Films Fabrication and Their Characterisation

To remove catalyst impurities, the grown MWCNTs are treated with 46% HF aqueous solution; a solid residue is afterwards extracted and washed with distilled water, then centrifuged and finally dried at 353 K for 12 h.

The final product is an sample of high purity MWCNTs, with a length in the range 100-200 μm and internal and external diameter of 10-30 nm and 5-10 nm, respectively (a TEM image of the MWCNTs is shown in FIG. 2).

The MWCNTs are used to fabricate random networks (MWCNTNs) in the form of thin films, with a fabrication procedure described below (FIG. 4):

9. 0.5 g of MWCNTs are suspended in 100 g of water in presence of 0.1 mg of sodium dodecyl sulfate and sonicated for 15 min

10. the solution is then vacuum filtered onto a membrane support

11. after drying, MWCNT films of different thicknesses and densities are removed from the support.

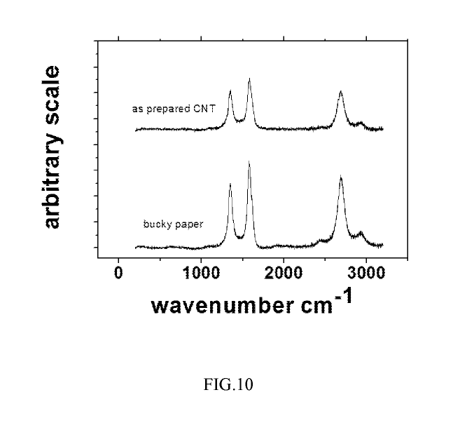

The described MWCNTN preparation procedure does not affect the characteristics of the MWCNTs as is verified by means of Raman spectroscopy. The MWCNTs Raman spectra in the range 1000-2000 cm⁻¹ are dominated by two Raman lines localized at ˜1590 cm⁻¹ (G-line) due to the in-plane vibration of the C—C bonds, and at ˜1300 cm⁻¹ (D line) attributed to disorder induced by defects and curvature in the nanotube lattice. Together, these bands can be used to evaluate the extent of any carbon-containing defects. By comparing the I_{D}/I_{G} ratios of the as-produced MWCNTs with that of the final MWCNTNs (FIG. 10), the demonstration that the treatments do not lead to an increase of the carbon nanotube defects is obtained.

### Example 3

### Manufacturing of CNT T-sensor

The so-obtained MWCNTNs (FIG. 5), typically with thickness of 100-300 um and diameter of 1-4 cm, can be folded and cut and are sufficiently robust to let stable contacts (by metal evaporation or, in a simplified embodiment, silver paint) to be formed and to withstand sudden and long thermal stresses. 4 metallic pads (contacts) are created with electrically conductive Ag paste, on samples of dimensions 2×6 mm² of MWCNTN, with thickness in the range 200-300 m to allow a precise measurement of the conductance. Due to the metallic nature of MWCNTs, the nanotube networks can be highly conductive and a 4-probe method is necessary to accurately measure their resistance, by overcoming the problem of a comparatively non-negligible contact resistance (FIG. 6).

### Example 4

### Behaviour of CNT T-sensor

The temperature coefficient of resistance TCR (a parameter often used to qualify a thermistor and defined as TCR=1/R₀.dR/dT where R is the resistance at temperature T and R₀ is the resistance at the standard temperature of 273,15 K) of MWCNTN is about −1·10⁻³ K⁻¹ . It may result lower compared for example with the ones for platinum temperature sensors. The performances of the device change with network characteristics as the constituting nanotubes, their density, their disposition and degree of entanglement. etc, and can be greatly improved.

Furthermore the MWCNTN sensor has the unmatched advantage of the wide range of sensitivity.

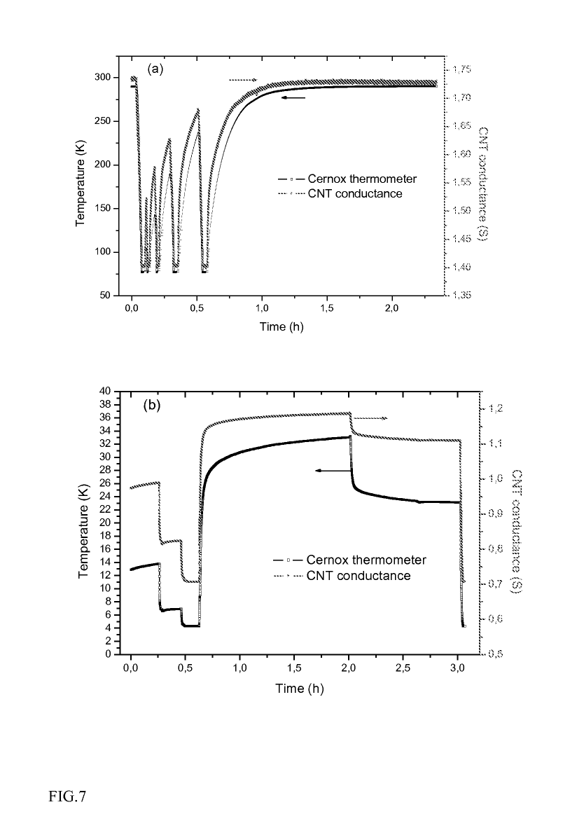

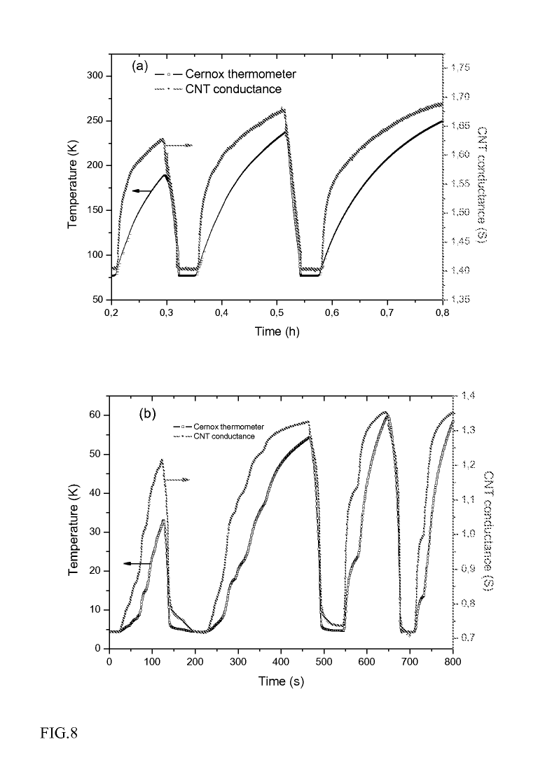

The MWCNTN sensor shows an excellent behavioural agreement with the temperature measured by commercial zirconium oxy-nitride, silicon or platinum thermistors and has a faster response (about 15%) to sudden and wide temperature changes (FIG. 7 and FIG. 8)

### Example 5

### Repeatability, Stability and Durability of MWCNT T-sensor

Used as sensing element, the MWCNTN shows an excellent repeatability, stability and durability.

Repeatability means the property of recovering the same minimum/maximum conductance when the temperature reaches the same minimum/maximum values and that is largely proven, an example is reported in FIG. 8. Stability is verified at several points of the working temperature range. FIG. 10 shows a continuous monitoring of the room and helium temperature for 16-20 hours which confirms the excellent agreement with the temperature measured by expensive commercial thermometers.

A temperature sensor exploiting the same MWCNTN has been used for several months and for a variety of measurements, has been subjected to sudden and long thermal and electrical stresses, and no degradation of its temperature sensing capabilities has been observed.

### ADVANTAGES OF THE INVENTION

The effective preparation synthesis by CCVD with high conversion of injected carbon (>95%)

A simple CNTN manufacturing method able to produce films with a stable resistance, even without the application of a cross-linking agent to prompt a cross-linking reaction between carbon nanotubes

The described CNTN preparation procedure does not affect the characteristics of the CNTs

The CNTN based temperature sensor shows an excellent behavioural agreement with the temperature measured for example by commercial zirconium oxy-nitride, silicon or platinum thermistors and has a faster response (of about 15%) to sudden and wide temperature changes.

Used as sensing element, the CNTNs show an excellent repeatability, stability and durability

The temperature coefficient of resistance TCR, on the measured samples, results lower than that of platinum sensor, but can be easily improved.

The CNTN based sensor is freely scalable in size down to nanometric dimensions.

The small size and the high thermal conductivity of CNTs results in a fast response.

The small size implies the possibility of performing local measurements or on small size systems

The small size implies a low power consumption and reduced perturbation for the measurement environment.

1. The production of a freestanding carbon nanotube network as sensing element in sensors.

2. The production of a freestanding carbon nanotube network as sensing element in sensors for the measurements of temperature.

3. The production of a freestanding carbon nanotube network as sensing element in sensors for the measurements of temperature in a wide range.

4. The production of a freestanding carbon nanotube network for temperature measurements according to any one of claims 1-3 where the carbon nanotubes are multiwalled.

5. The production of a freestanding carbon nanotube network for temperature measurements according to any one of claims 1-3 where the carbon nanotubes are multiwalled and without functionalisation

6. The production of a freestanding carbon nanotube network for temperature measurements according to any one of claims 1-3 where the carbon nanotubes are multiwalled, purified and without functionalisation

7. The production of a freestanding carbon nanotube network for temperature measurements according to any one of claims 1-3 where the carbon nanotubes are single- or double-walled.

8. The production of a carbon nanotube network for temperature sensing purposes, according to claims 1-7, in the form of freestanding film, with carbon nanotubes with random or oriented disposition

9. The production of a carbon nanotube network for temperature sensing purposes, according to any one of claims 1-8, where carbon nanotube have length in the range 0.01-10 mm.

10. The production of a carbon nanotube network for temperature sensing purposes, according to any one of claims 1-8, where carbon nanotubes have external diameter 1-200 nm.

11. The production of a carbon nanotube network for temperature sensing purposes, according to any one of claims 1-8, where carbon nanotubes have internal diameter 0.5-150 nm.

12. The production of a carbon nanotube network for temperature sensing purposes, according to any one of claims 1-11, where carbon nanotubes are obtained by a high yield CCVD synthesis technique.

13. A method to efficiently synthesize high purity multiwalled carbon nanotubes based on ethylene CCVD on Co/Fe—Al₂O₃ catalyst.

14. A sensor comprising a sensing element made by a CNTN according to any one of claims 1-12, with 2 contacts used to measure its conductance/resistance which is converted to temperature.

15. A sensor comprising a sensing element made by a CNTN according to any one of claims 1-12, with 4 contacts used to measure its conductance/resistance which is converted to temperature.

16. A sensor comprising a sensing element made by a CNTN according to any one of claims 1-12, with 6 contacts used to measure its conductance/resistance which is converted to temperature.

17. A sensor comprising a sensing element made by a MWCNTN, with un-functionalised and spontaneously interconnected nanotubes, with 2, 4 or 6 metal contacts to measure its conductance/resistance which is converted to temperature.

18. A sensor comprising a sensing element made by a MWCNTN, with purified, un-functionalised and spontaneously interconnected nanotubes, with 2, 4 or 6 metal contacts to measure its conductance/resistance which is converted to temperature.

19. A series of sensors according to any one of claims 14-18

20. Sensors in parallel according to any one of claims 14-18

21. Sensors in series and parallel according to any one of claims 14-18

22. A procedure of manufacturing carbon nanotube networks in the form of films based on vacuum filtration of a CNT containing solution

23. A procedure of manufacturing carbon nanotube networks according to any one of claims 1-12 e 22 with thickness in the range 10 mm-5 cm.

24. A procedure of manufacturing carbon nanotube networks according to any one of claims 1-12 with dimensions in the range 10 nm -10 cm.

25. A method to form thermal stable electrical contacts (pads) on thin films of carbon nanotubes to measure the film conductance/resistance.

26. A sensor or sensors according to any one of claims 14-21 covered by a polymeric film by one/two side/s.

27. A sensor or sensors according to any one of claims 14-21 encapsulated into a polymer.

28. The production of sensors according to any one of claims 26-27.
